(19) United States
(12) Patent Application Publication
(10) Pub. No.: US 2015/0014579 A1
(43) Pub. Date: Jan. 15, 2015

(54) POLISHING COMPOSITION AND METHOD FOR PRODUCING SEMICONDUCTOR SUBSTRATE

(71) Applicant: FUJIMI INCORPORATED, Kiyosu-shi, Aichi (JP)

(72) Inventors: Toshihiro Miwa, Kiyosu-shi (JP); Hiroyuki Oda, Kiyosu-shi (JP); Shinichiro Takami, Kiyosu-shi (JP); Shuhei Takahashi, Kiyosu-shi (JP); Yutaka Inoue, Kiyosu-shi (JP)

(21) Appl. No.: 14/376,547

(22) PCT Filed: Feb. 5, 2013
(86) PCT No.: PCT/JP2013/052585

§ 371 Date: Aug. 4, 2014

(30) Foreign Application Priority Data
Feb. 10, 2012 (JP) 2012-027495

(51) Int. Cl. H01L 21/304; B24B 37/04; C09G 1/02

(52) U.S. Cl. CPC H01L 21/304; C09G 1/02; B24B 37/044
USPC 252/79.5; 252/79.1; 451/41

(57) ABSTRACT

A polishing composition contains: silicon dioxide having an average primary particle diameter of 40 nm or more as calculated from the specific surface area determined by the BET method; a nitrogen-containing water-soluble polymer; and a basic compound. The value of B/A is 1 or more and less than 7,000 and the value of C/A is 5,000 or more and less than 1,500,000 when in one liter of the polishing composition, A is defined as the number of silicon dioxide, B is defined as the number of monomer units of the nitrogen-containing water-soluble polymer, and C is defined as the number of molecules of the basic compound. Alternatively, the value of B/A is 1 or more and less than 7,000 and the value of C/A is 5,000 or more and less than 100,000. The polishing composition is used, for example, for polishing a semiconductor substrate.

### TECHNICAL FIELD

The present invention relates to a polishing composition and a semiconductor substrate production method in which a semiconductor substrate is polished with the polishing composition.

### BACKGROUND ART

The surface of a semiconductor substrate, such as silicon wafer, is polished several times including primary polishing. The edge of a semiconductor substrate is also polished. For these types of polishing, a polishing composition is used that contains, for example, silicon dioxide having an average primary particle diameter of 40 nm or more and a water-soluble polymer (see Patent document 1).

Due to high-performance and high-density integration of a semiconductor device, the improvement in the surface quality of a semiconductor substrate is recently required. In view of improving the quality of a polished product, it is important, in particular, to maintain the edge shape of a polishing object and to reduce the surface roughness or the difference in level. In these circumstances, for example, a polishing composition is known that contains relatively small silica particles for reducing the roll-off (end face sagging) of a hard disk substrate (see Patent document 2). A polishing composition is also known that contains colloidal silica and a water-soluble polymer compound for reducing the irregularities of a substrate surface (see Patent document 3). A polishing composition is also known that contains polyvinylpyrrolidone for reducing surface defects (see Patent document 4). A polishing composition is also known that contains a surfactant for reducing etching of regions on a silicon wafer not to be processed (see Patent document 5).

### PRIOR ART DOCUMENTS

Patent document 1: Japanese Laid-Open Patent Publication No. 2004-128069
Patent document 2: Japanese Laid-Open Patent Publication No. 2009-160676
Patent document 3: Japanese Laid-Open Patent Publication No. 2-158684
Patent document 4: Japanese Laid-Open Patent Publication No. 2008-53415
Patent document 5: International Publication No. WO 2005/029563

### SUMMARY OF THE INVENTION

### Problems that the Invention is to Solve

In view of improving the quality of a polished product, it is important to maintain the edge shape of a polishing object and to reduce the surface roughness or the difference in level, as described above. On the other hand, in view of responding to the increased quantity demanded for a polished product, it is important to provide a polishing composition for achieving a high polishing rate.

Accordingly, it is an objective of the present invention to provide a polishing composition that easily improves the quality of a polished product by maintaining the edge shape of a polishing object and reducing the surface roughness or the difference in level and easily achieves a high polishing rate. It is another objective of the present invention to provide a semiconductor substrate production method using the polishing composition.

### Means for Solving the Problems

In order to achieve the objectives described above and in accordance with a first aspect of the present invention, provided is a polishing composition to be used for polishing both surfaces of a semiconductor substrate. The polishing composition contains silicon dioxide, a nitrogen-containing water-soluble polymer, and a basic compound. The silicon dioxide has an average primary particle diameter of 40 nm or more as calculated from the specific surface area determined by the BET method. The value of B/A is 1 or more and less than 7,000 and the value of C/A is 5,000 or more and less than 1,500,000 when in one liter of the polishing composition, A is defined as the number of silicon dioxide, B is defined as the number of monomer units of the nitrogen-containing water-soluble polymer, and C is defined as the number of molecules of the basic compound.

In accordance with a second aspect of the present invention, provided is a polishing composition containing silicon dioxide, a nitrogen-containing water-soluble polymer, and a basic compound. The silicon dioxide has an average primary particle diameter of 40 nm or more as calculated from the specific surface area determined by the BET method. The value of B/A is 1 or more and less than 7,000 and the value of C/A is 5,000 or more and less than 100,000 when in one liter of the polishing composition, A is defined as the number of silicon dioxide, B is defined as the number of monomer units of the nitrogen-containing water-soluble polymer, and C is defined as the number of molecules of the basic compound.

The nitrogen-containing water-soluble polymer has a weight average molecular weight of preferably less than 1,500,000.

The silicon dioxide has true specific gravity of preferably 1.7 or more.

The basic compound preferably includes a potassium compound and a quaternary ammonium compound.

In accordance with a third aspect of the present invention, a method for producing a semiconductor substrate is provided that includes polishing a semiconductor substrate with the polishing composition of the first or second aspect described above.

### Effects of the Invention

According to the polishing composition and the method for producing a semiconductor substrate of the present invention, the quality of a polished product can be easily improved by maintaining the edge shape of a polishing object and reducing the surface roughness or the difference in level, and a high polishing rate can be easily obtained.

### MODES FOR CARRYING OUT THE INVENTION

A first embodiment of the present invention will be described below.

### First Embodiment

The polishing composition of the present embodiment is prepared by mixing silicon dioxide, a nitrogen-containing water-soluble polymer, and a basic compound with water. Accordingly, the polishing composition contains silicon dioxide, a nitrogen-containing water-soluble polymer, a basic compound, and water. The polishing composition is used, for example, for polishing both surfaces of a semiconductor substrate, such as silicon substrate.

### <Silicon Dioxide>

Silicon dioxide contained in the polishing composition functions to physically polish a surface to be polished.

Examples of silicon dioxide for use include colloidal silica, fumed silica, and sol-gel silica. Use of colloidal silica or fumed silica, and in particular use of colloidal silica is preferable for reducing scratches occurring on the surface of a polished semiconductor substrate. One type of silicon dioxides may be used alone or in combination with other one or more types.

The silicon dioxide in the polishing composition has an average primary particle diameter of 40 nm or more, preferably 45 nm or more, and more preferably 70 nm or more, as calculated from the specific surface area determined by the BET method. When the average primary particle diameter of the silicon dioxide is 40 nm or more, the surface roughness or the difference in level is easily reduced.

The average primary particle diameter of the silicon dioxide in the polishing composition is also preferably less than 100 nm. When the average primary particle diameter of the silicon dioxide is less than 100 nm, the storage stability of the polishing composition is further improved. The storage stability means the stability of the physical properties of the composition itself before and after storage of the polishing composition in a container for a predetermined period and the stability of polishing characteristics when the composition is used in polishing.

The ratio of the major axis to the minor axis of the silicon dioxide in the polishing composition is preferably 1.10 or more, and more preferably 1.15 or more. When the silicon dioxide has a ratio of the major axis to the minor axis of 1.10 or more, a high polishing rate is easily obtained and the effect for reducing the surface roughness or the difference in level is enhanced.

The ratio of the major axis to the minor axis of the silicon dioxide means an average of the values each obtained by dividing the length of the long side of a minimum rectangle circumscribing one of silicon dioxide particles within the visual field of a scanning electron microscope by the length of the short side of the same rectangle. The average can be obtained by using common image analysis software program.

The ratio of the major axis to the minor axis of the silicon dioxide in the polishing composition is also preferably less than 3.00, and more preferably less than 2.00. When the silicon dioxide has a ratio of the major axis to the minor axis of less than 3.00, the storage stability of the polishing composition is further improved.

The true specific gravity of the silicon dioxide in the polishing composition is preferably 1.7 or more, more preferably 2.0 or more, and still more preferably 2.1 or more. As the true specific gravity of the silicon dioxide increases, a high polishing rate can be easily obtained and the effect for reducing the surface roughness or the difference in level can be easily enhanced.

The true specific gravity of the silicon dioxide is calculated from the dry weight of the silicon dioxide particles and the gross weight of the silicon dioxide particles after immersed in a known volume of ethanol.

The content of the silicon dioxide in the polishing composition is preferably 0.6% by mass or more, more preferably 0.8% by mass or more, and still more preferably 1.0% by mass or more. As the content of the silicon dioxide increases, a high polishing rate is easily obtained with more enhanced effect for reducing the surface roughness or the difference in level.

The content of the silicon dioxide in the polishing composition is preferably less than 10% by mass. When the content of the silicon dioxide is less than 10% by mass, the storage stability of the polishing composition is further improved and an economic advantage is obtained.

### <Nitrogen-Containing Water-Soluble Polymer>

A nitrogen-containing water-soluble polymer contained in the polishing composition functions to maintain the flatness of a semiconductor substrate along the central part to the edge.

The nitrogen-containing water-soluble polymer for use is not specifically limited as long as one or more nitrogen atoms are contained in a monomer unit, or one or more nitrogen atoms are contained in a side chain. For example, an amine, an imine, an amide, an imide, a carbodiimide, a hydrazide, or a urethane compound may be used. The nitrogen-containing water-soluble polymer may be any of chain-type, ring-type, primary-type, secondary-type, and tertiary-type. The nitrogen-containing water-soluble polymer may include a salt structure having a nitrogen atom as a cation. Examples of a nitrogen-containing water-soluble polymer including a salt structure include a quaternary ammonium salt. Examples of other nitrogen-containing water-soluble polymers include a polycondensation-type polyamide (such as water-soluble nylon), a polycondensation-type polyester (such as water-soluble polyester), a polyaddition-type polyamine, a polyaddition-type polyimine, a polyaddition-type (meth)acrylic amide, a water-soluble polymer having a nitrogen atom in at least a part of main alkyl chain, and a water-soluble polymer having a nitrogen atom in at least a part of side chain. The water-soluble polymer having a nitrogen atom in a side chain may include a water-soluble polymer having a quaternary nitrogen in a side chain.

Specific examples of polyaddition-type nitrogen-containing water-soluble polymers include polyvinylimidazole, polyvinylcarbazole, polyvinylpyrrolidone, polyvinylcaprolactam, and polyvinylpiperidine. The nitrogen-containing water-soluble polymer may partially include a structure having hydrophilicity, such as a vinyl alcohol structure, a methacrylic acid structure, vinyl sulfonic acid structure, a vinyl alcohol carboxylic acid ester structure, and an oxyalkylene structure. The polymer may include two or more structures thereof, such as a di-block type, a tri-block type, a random type, and an alternate type. A part or all of the molecules of the nitrogen-containing water-soluble polymer may include cations, anions, both of anions and cations, or nonions. One type of nitrogen-containing water-soluble polymers may be used alone or in combination with other one or more types.

Among nitrogen-containing water-soluble polymers, polyvinylpyrrolidone, a copolymer including polyvinylpyrrolidone in a part of structure, polyvinylcaprolactam, and a copolymer including polyvinylcaprolactam in a part of structure are preferable because of excellent controllability for polishing the edge of a semiconductor substrate. In particular, polyvinylpyrrolidone is most preferred.

The weight average molecular weight of the nitrogen-containing water-soluble polymer in the polishing composition is preferably less than 1,500,000, more preferably less than 500,000, still more preferably less than 100,000, yet still more preferably less than 80,000, and most preferably less than 50,000, in terms of polyethylene oxide. When the nitrogen-containing water-soluble polymer has a weight average molecular weight of less than 1,500,000, the storage stability of the polishing composition is easily improved.

The weight average molecular weight of the nitrogen-containing water-soluble polymer in the polishing composition is also preferably 1,000 or more, and more preferably 20,000 or more. When the nitrogen-containing water-soluble polymer has a weight average molecular weight of 1,000 or more, the edge shape of a semiconductor substrate is more easily maintained.

The content of the nitrogen-containing water-soluble polymer in the polishing composition is preferably 0.0001% by mass or more. When the content of the nitrogen-containing water-soluble polymer is 0.0001% by mass or more, the edge shape of a semiconductor substrate is more easily maintained.

The content of the nitrogen-containing water-soluble polymer in the polishing composition is also preferably less than 0.002% by mass, more preferably less than 0.001% by mass, and still more preferably less than 0.0005% by mass. When the content of the nitrogen-containing water-soluble polymer is less than 0.002% by mass, a high polishing rate is more easily obtained.

### <Basic Compound>

The basic compound functions to chemically polish a surface to be polished, and to improve the storage stability of the polishing composition.

Specific examples of basic compounds include a hydroxide or salt of an alkaline metal, a quaternary ammonium hydroxide or a salt thereof, ammonia, and an amine. Examples of the alkaline metal include potassium and sodium. Examples of the salt include a carbonate, hydrogen carbonate, sulfate, and acetate. Examples of the quaternary ammonium include tetramethylammonium, tetraethylammonium, and tetrabutylammonium.

A quaternary ammonium hydroxide compound means a quaternary ammonium hydroxide or a salt thereof, and specific examples thereof include tetramethylammonium hydroxide, a tetraethylammonium hydroxide, and tetrabutylammonium hydroxide.

Specific examples of the amine include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, N-methylpiperazine, and guanidine. One type of basic compounds may be used alone or in combination with other one or more types.

Among basic compounds, at least one selected from ammonia, an ammonium salt, an alkaline metal hydroxide, an alkaline metal salt, and a quaternary ammonium hydroxide compound is preferably used, and at least one selected from ammonia, a potassium compounds sodium hydroxide, a quaternary ammonium hydroxide compound, ammonium hydrogen carbonate, ammonium carbonate, sodium hydrogen carbonate, and sodium carbonate is more preferably used.

The polishing composition preferably contains a potassium compound and a quaternary ammonium hydroxide compound as basic compounds. Examples of the potassium compound include a hydroxide or salt of potassium, such as potassium hydroxide, potassium carbonate, potassium hydrogen carbonate, potassium sulfate, potassium acetate, and potassium chloride. Most preferably, the polishing composition contains potassium hydroxide, potassium carbonate, and tetramethyl ammonium hydroxide as basic compounds.

The content of the basic compound in the polishing composition is preferably 0.01% by mass or more, and more preferably 0.03% by mass or more. As the content of the basic compound increases, a high polishing rate is easily obtained.

The content of the basic compound in the polishing composition is also preferably less than 0.2% by mass, and more preferably less than 0.1% by mass. As the content of the basic compound decreases, the edge shape of a semiconductor substrate is easily maintained.

The polishing composition of the present embodiment satisfies the following conditions X1 and X2 when in one liter of the polishing composition, A is defined as the number of silicon dioxide, B is defined as the number of monomer units of the nitrogen-containing water-soluble polymer, and C is defined as the number of molecules of the basic compound.

Condition X1: the value of B/A is 1 or more and less than 7,000; and

Condition X2: the value of C/A is 5,000 or more and less than 1,500,000.

The value of B/A defined in condition X1 represents the degree of protection against the physical action of the polishing composition. By setting the degree of protection to a proper range against the physical action of the polishing composition, both of the quality of a polished product and the polishing rate are easily enhanced.

When the polishing composition has a value of B/A of 1 or more, the effect for reducing the surface roughness or the difference in level and the effect for maintaining the edge shape of a semiconductor substrate are enhanced. From the view point of the effects, the value of B/A is preferably 10 or more, more preferably 30 or more, and most preferably 100 or more.

When the polishing composition has a value of B/A of less than 7,000, the effect for reducing the surface roughness or the difference in level and the effect for improving the polishing rate are enhanced. From the view point of the effects, the value of B/A is preferably less than 4,000, more preferably less than 1,000, still more preferably less than 500, and most preferably less than 200.

The value of A, which is defined as the number of silicon dioxide in one liter of the polishing composition, and the value of B, which is defined as the number of monomer units of the nitrogen-containing water-soluble polymer, are given by the following expressions (1) and (2).

$$\begin{matrix}Expression 1 & \\ A = 1.91 \times {10}^{22} \times \frac{Content of silicon dioxide [ \% by mass ]}{\begin{matrix}{( BET particle diameter of silicon dioxide [ nm ] )}^{3} \times \\ ( True specific gravity of silicon dioxide [ g \text{/} {cm}^{3} ] )\end{matrix}} & ( 1 )\end{matrix}$$

In Expression (1), 1.91×10²² is a constant determined by the expression for calculating the volume of silicon dioxide and the conversion of units. When the polishing composition contains two or more kinds of silicon dioxide, the number of silicon dioxide is calculated for each kind and summation thereof is regarded as A.

$$\begin{matrix}Expression 2 & \\ B = 6.02 \times {10}^{24} \times \frac{ \begin{matrix}Content of nitrogen \text{-} containing \\ water \text{-} soluble polymer [ \% by mass ]\end{matrix}}{\begin{matrix}Molecular weight of monomer of nitrogen \\ \text{-} containing water \text{-} soluble polymer [ g \text{/} mol ]\end{matrix}} & ( 2 )\end{matrix}$$

In Expression (2), 6.02×10²⁴ is a constant determined by the Avogadro constant and the conversion of units. When the polishing composition contains two or more kinds of nitrogen-containing water-soluble polymer, the number of monomer units of the nitrogen-containing water-soluble polymer is calculated for each kind and summation thereof is regarded as B.

The value of C/A defined in condition X2 represents the ratio of the chemical action to the physical action of the polishing composition. By setting the ratio of the chemical action to the physical action of the polishing composition to a proper range, both of the quality of a polished product and the polishing rate are easily enhanced.

When the polishing composition has a value of C/A of 5,000 or more, the effect for reducing the surface roughness or the difference in level and the effect for improving the polishing rate are enhanced. From the view point of the effects, the value of C/A is preferably 10,000 or more, more preferably 20,000 or more, and most preferably 40,000 or more.

When the polishing composition has a value of C/A of less than 1,500,000, the effect for reducing the surface roughness or the difference in level and the effect for maintaining the edge shape of a semiconductor substrate are enhanced. From the view point of the effects, the value of C/A is preferably less than 600,000, more preferably less than 300,000, still more preferably less than 100,000, and most preferably less than 60,000.

The value of C, which is defined as the number of molecules of the basic compound, is given by the following expression (3).

$$\begin{matrix}Expression 3 & \\ C = 6.02 \times {10}^{24} \times \frac{Content of basic compound [ \% by mass ]}{Molecular weight of basic compound [ g \text{/} mol ]} & ( 3 )\end{matrix}$$

In Expression (3), 6.02×10²⁴ is a constant determined by the Avogadro constant and the conversion of units. When the polishing composition contains two or more kinds of basic compounds, the number of molecules of the basic compound is calculated for each kind and summation thereof is regarded as C.

### <Chelating Agent>

The polishing composition may contain a chelating agent. The chelating agent in the polishing composition functions to capture metal impurities in the polishing system so as to form a complex, preventing the metal impurities from remaining on a semiconductor substrate.

Examples of chelating agents include an aminocarboxylic acid chelating agent and an organic phosphonic acid chelating agent. Specific examples of aminocarboxylic acids chelating agent include ethylenediaminetetraacetatic acid, sodium ethylenediaminetetraacetate, nitrilotriacetic acid, sodium nitrilotriacetate, ammonium nitrilotriacetate, hydroxyethyl ethylenediaminetriacetic acid, sodium hydroxyethyl ethylenediaminetriacetate, diethylenetriaminepentaacetic acid, sodium diethylenetriaminepentaacetate, triethylenetetraaminehexaacetic acid, and sodium triethylenetetraaminehexaacetate.

Specific examples of organic phosphonic acid chelating agent include 2-aminoethylphosphonic acid, 1-hydroxyethylidene-1,1-diphosphonic acid, aminotri(methylenephosphonic acid), ethylenediaminetetrakis(methylenephosphonic acid), diethylenetriaminepenta(methylenephosphonic acid), triethylenetetraminehexa(methylenephosphonic acid), ethane-1,1-diphosphonic acid, ethane-1,1,2-triphosphoric acid, ethane-1-hydroxy-1,1-diphosphonic acid, ethane-1-hydroxy-1,1,2-triphosphonic acid, ethane-1,2-dicarboxy-1,2-diphosphonic acid, methanehydroxy phosphonic acid, 2-phosphonobutane-1,2-dicarboxylic acid, 1-phosphonobutane-2,3,4-tricarboxylic acid, and α-methyl phosphonosuccinic acid. One type of chelating agents may be used alone or in combination with other one or more types.

Among chelating agents, an organic phosphonic acid chelating agent is preferred, and ethylenediaminetetrakis(methylenephosphonic acid) is more preferred.

The content of the chelating agent in the polishing composition is preferably 0.0001% by mass or more, and more preferably 0.0005% by mass or more. As the content of the chelating agent increases, the effect for preventing metal impurities from remaining on a semiconductor substrate is enhanced.

The content of the chelating agent in the polishing composition is also preferably less than 0.01% by mass, and more preferably less than 0.005% by mass. As the content of the chelating agent decreases, the storage stability of the polishing composition is further maintained.

### <Water>

Water contained in the polishing composition functions to dissolve or disperse the other components. Water in which the total content of transition metal ions is 100 ppb or less is preferably used in order not to inhibit the actions of the other components. The purity of water can be enhanced by an operation such as removal of impurity ions using an ion exchange resin, removal of foreign matters using a filter, and distillation. Specifically, ion-exchange water, pure water, ultrapure water, or distilled water is preferably used.

The pH of the polishing composition is preferably within the range of 8 to 12, and more preferably within the range of 9 to 11.

In preparation of the polishing composition, a well-known mixing apparatus such as a blade-type stirrer, an ultrasonic disperser, and a homomixer can be used. The raw materials of the polishing composition may be mixed all together at the same time or may be sequentially mixed in any order.

In the following, the method for polishing a semiconductor substrate using the polishing composition is described together with the operation of the polishing composition.

In polishing the surface of a semiconductor substrate with the polishing composition, a polishing pad is pressed against the semiconductor substrate surface while the polishing composition is supplied onto the semiconductor substrate surface, and the semiconductor substrate and the polishing pad are rotated. As a polishing machine, a double side polishing machine is used that polishes simultaneously both surfaces of a semiconductor substrate.

The polishing composition of the present embodiment contains silicon dioxide having an average primary particle diameter of 40 nm or more as calculated from the specific surface area determined by the BET method, a nitrogen-containing water-soluble polymer, and a basic compound, and satisfies the conditions X1 and X2 described above. Accordingly, the polishing composition applies a suitable physical action and a suitable chemical action to the surface of a semiconductor substrate, and imparts a suitable protection against the physical action to the semiconductor substrate surface. As a result, the surface roughness and the difference in level of a semiconductor substrate is easily reduced. For example, a semiconductor substrate to be polished has an engraved mark part produced with a laser marker in some cases. The polishing composition of the present embodiment is suitably used for reducing the surface roughness or the difference in level of the engraved mark part of a semiconductor substrate. Furthermore, the polishing composition allows the control of polishing at the edge of a semiconductor substrate. More specifically, the edge of a semiconductor substrate is prevented from being excessively polished, so that the edge shape of a semiconductor substrate is easily maintained. As a result, for example, the occurrence of edge roll-off of a semiconductor substrate to be polished is easily reduced. In addition, a high polishing rate is easily obtained.

The present embodiment described in detail above provides the following effects.

(1) In comparison between double side polishing and one side polishing of a semiconductor substrate, the double side polishing is performed to give priority to polishing efficiency in many cases. In the case of double side polishing requiring high polishing rate, it is difficult to maintain the edge shape of a semiconductor substrate (or to control the edge shape). The polishing composition of the present embodiment is used for polishing both surfaces of a semiconductor substrate. The polishing composition contains silicon dioxide having an average primary particle diameter of 40 nm or more as calculated from the specific surface area determined by the BET method, a nitrogen-containing water-soluble polymer, and a basic compound, and satisfies the conditions X1 and X2 described above. Accordingly, the edge shape of a semiconductor substrate is maintained, while the surface roughness or the difference in level is easily reduced and a high polishing rate is easily obtained. That is, the polishing composition of the present embodiment has excellent effects for easily maintaining the edge shape of a semiconductor substrate and easily reducing the surface roughness or the difference in level even in double side polishing with priority given to polishing rate.

(2) When the weight average molecular weight of the nitrogen-containing water-soluble polymer is less than 1,500,000, the storage stability of the polishing composition is easily improved.

(3) When the specific gravity of the silicon dioxide is 1.7 or more, a high polishing rate is more easily obtained and the effect for reducing the surface roughness or the difference in level is more easily enhanced.

(4) The method for manufacturing a semiconductor substrate using the polishing composition of the present embodiment maintains the edge shape of a semiconductor substrate, while easily reducing the surface roughness or the difference in level and easily obtaining a high polishing rate.

### Second Embodiment

A second embodiment of the present invention will be described below, with a focus on the difference from the first embodiment. The polishing composition of the second embodiment has a value of C/A in the range different from that of the polishing composition of the first embodiment. The polishing composition of the present embodiment can be used not only in double side polishing of a semiconductor substrate, but also in one side polishing or edge polishing of a semiconductor substrate.

The polishing composition of the present embodiment satisfies the following conditions Y1 and Y2 when in one liter of the polishing composition, A is defined as the number of silicon dioxide, B is defined as the number of monomer units of the nitrogen-containing water-soluble polymer, and C is defined as the number of molecules of the basic compound.

Condition Y1: the value of B/A is 1 or more and less than 7,000; and

Condition Y2: the value of C/A is 5,000 or more and less than 100,000.

The polishing composition of the present embodiment contains silicon dioxide having an average primary particle diameter of 40 nm or more as calculated from the specific surface area determined by the BET method, a nitrogen-containing water-soluble polymer, and a basic compound, and satisfies the conditions Y1 and Y2 described above. Accordingly, the edge shape of a polishing object is maintained, while the surface roughness or the difference in level is easily reduced and a high polishing rate is easily obtained. In particular, having a value of C/A of less than 100,000, the present embodiment facilitates further enhancing the effect for reducing the surface roughness or the difference in level and the effect for maintaining the edge shape of a semiconductor substrate. The polishing composition of the present embodiment also can achieve the similar effects (2) to (4) described in the first embodiment.

Polishing of one or both surfaces of a semiconductor substrate is divided into a plurality of stages including a first polishing step as an initial step, a second polishing step that is performed subsequent to the first polishing step, and a final polishing step that is performed for the purpose of finishing. Among the steps, polishing steps on and after the second polishing step are performed for each surface of a semiconductor substrate in many cases. In such one side polishing, it is further required to maintain the edge shape of a semiconductor substrate and reduce the surface roughness or the difference in level in some cases, causing difficulty in obtaining a high polishing rate. In this circumstance, the polishing composition of the present embodiment is suitably used in one side polishing, for example, in any of polishing steps on and after the second polishing step from the viewpoint of improvement in the quality of a polished semiconductor substrate and improvement in the polishing efficiency.

The embodiments described above may be modified as follows.
The polishing composition may further contain a known additive such as a preservative agent and an antifungal agent, if needed. Specific examples of preservative agents and antifungal agents include isothiazoline compounds, para-oxybenzoates, and phenoxyethanol.
The polishing composition may further contain a hydrate, chloride, carbonate, hydrogen carbonate, sulfate, or acetate of sodium, if needed.
The polishing composition may be of a one-pack type, or may be a multi-pack type including two or more packs.
The polishing composition may be prepared by diluting an undiluted solution of the polishing composition with water. For example, by diluting an undiluted solution of the polishing composition after storage or transportation, the polishing composition can be prepared when used.
The polishing composition may be reused for polishing after once used for polishing. When a used polishing composition is reused for polishing, a component or components lacking in the polishing composition may be complemented.
The polishing pad used in polishing using the polishing composition is not particularly limited. The polishing pad may be of a polyurethane type, a nonwoven type, a suede type, an abrasive grain-containing type, or a no abrasive grain-containing type.
The polishing composition of the second embodiment may be used not only for polishing a semiconductor substrate, such as a silicon substrate and a silicon oxide substrate, but also for producing a polished product by polishing, for example, a plastic substrate, a glass substrate, or a quartz substrate.

### EXAMPLES

Next, the embodiments will be more specifically described with reference to examples and comparative Examples in the following.

### (A. Double Side Polishing of Semiconductor Substrate)

Polishing compositions of Examples A1 to A13 and Comparative Examples A1 to A9 were prepared by mixing silicon dioxide, a nitrogen-containing water-soluble polymer, and a basic compound with ion-exchange water. The details for each of the polishing compositions are shown in Table 1.

The “BET particle diameter” column of Table 1 shows the average primary particle diameter calculated from the specific surface area (BET method) determined using “Flow SorbII 2300”, made by Micromeritics Instrument Corporation. The “A” column of Table 1 shows the number of silicon dioxide in one liter of a polishing composition. In the “water-soluble polymer” column of Table 1, “PVP” represents polyvinylpyrrolidone, “PVCL” represents polyvinylcaprolactam, “PAA” represents polyacrylic acid, “PVA” represents polyvinyl alcohol, and “PEG” represents polyethylene glycol. The “B” column of Table 1 shows the number of monomer units of a nitrogen-containing water-soluble polymer in one liter of a polishing composition or the number of monomer units of a water-soluble polymer in one liter of a polishing composition. In the “basic compound” column of Table 1, “KOH” represents potassium hydroxide, “K2CO3” represents potassium carbonate, and “TMAH” represents tetramethylammonium hydroxide. The “C” column in the “basic compound” column of Table 1 shows the number of molecules of a basic compound in one liter of a polishing composition.

A silicon substrate was polished under the polishing condition 1 described in Table 2 with each of the polishing compositions of Examples A1 to A13 and Comparative Examples A1 to A9. The silicon substrate used had a diameter of 300 mm, p-type conduction, a crystal orientation of <100>, and a resistivity of 0.1 Ω·cm or more and less than 100 Ω·cm.

### <Polishing Rate>

The thickness of a silicon substrate before polishing and the thickness of the silicon substrate after polishing under the polishing condition 1 were measured with Nanometro 300TT, made by Kuroda Precision Industries Ltd., and the difference in thickness before and after polishing was divided by polishing time so as to calculate the polishing rate. In the “polishing rate” column of Table 1, “oo” represents a polishing rate of 0.40 μm/min or more, “o” represents a polishing rate of 0.35 μm/min or more and less than 0.40 μm/min, “Δ” represents a polishing rate of 0.30 μm/min or more and less than 0.35 μm/min, and “x” represents a polishing rate of less than 0.30 μm/min.

### <Surface Roughness or Difference in Level>

The surface roughness Ra of a silicon substrate after polishing under the polishing condition 1 was measured with “ZYGO New View 5010”, made by Zygo Corporation. The surface roughness Ra is a parameter that indicates the average of amplitude in the height direction of a roughness curve, representing the arithmetic average of surface height of a silicon substrate within a fixed visual field. In the “surface roughness Ra” column of Table 1, “oo” represents a surface roughness Pa of less than 7.0 Å, “o” represents 7.0 Å or more and less than 8.0 Å, “Δ” represents 8.0 Å or more and less than 10.0 Å, and “x” represents 10.0 Å or more.

The surface roughness Rt of a silicon substrate after polishing under the polishing condition 1 was measured with HRP340, made by KLA-Tencor Corporation. The surface roughness Rt is a parameter that indicates the maximum sectional height of a roughness curve, representing the difference between the highest part and the lowest part of the surface height of a silicon substrate within a fixed visual field. In the “surface roughness Rt” column of Table 1, “oo” represents a surface roughness Rt of less than 300 Å, “o” represents 300 Å or more and less than 700 Å, “Δ” represents 700 Å or more and less than 1,500 Å, and “x” represents 1,500 Å or more.

### <Edge Shape A1>

The SFQR value indicating the flatness of a substrate was measured for each of the silicon substrates before polishing and the silicon substrates after polishing under the polishing condition 1, so that the edge shape of the silicon substrate after polishing was evaluated based on the difference in the SFQR value before and after polishing. More specifically, 30 pieces of 25 mm square regions were arranged on each of the substrates, excluding notches on the periphery of the substrate, for measurement of the SFQR value for each of the regions with Nanometro 300TT, made by Kuroda Precision Industries Ltd., and the average of the difference in the SFQR value between before and after polishing was obtained. In the “edge shape A1” column of Table 1, “oo” represents an average of less than 1.0 μm, “o” represents an average of 1.0 μm or more and less than 1.5 μm, “Δ” represents 1.5 μm and more and less than 2.0 μm, and “x” represents 2.0 μm or more.

### <Edge Shape A2>

A silicon substrate was polished under the polishing condition 2 described in Table 3 with each of the polishing compositions of Examples A1, A2, and A12 and Comparative Example A8. The silicon substrate used had a diameter of 300 mm, p-type conduction, a crystal orientation of <100>, and a resistivity of 0.1 Ω·cm or more and less than 100 Ω·cm. The thickness of a silicon substrate before polishing and the thickness of the silicon substrate after polishing each were measured at a position 1 mm inside from the periphery of the substrate with Nanometro 300TT, made by Kuroda Precision Industries Ltd., and the edge shape of the silicon substrate after polishing was evaluated based on the difference before and after polishing. In the “edge shape A2” column of Table 1, “oo” represents a difference value of less than 0.02 μm, “o” represents 0.02 μm or more and less than 0.04 μm, “Δ” represents 0.04 μm or more and less than 0.06 μm, and “x” represents 0.06 μm or more.

TABLE 1

| | Silicon dioxide | | | | Water-soluble polymer | | | | |
|---|---|---|---|---|---|---|---|---|---|
| | BET | True | | | | Weight | | | Basic |
| | particle | specific | Content | | | average | Content | | com- |
| | diameter | gravity | [% by | | | molecular | [% by | | pound |
| | [nm] | [g/cm³] | mass] | A | Kind | weight | mass] | B | Kind |
| Example A1 | 50 | 2.2 | 1.2 | 8.33 × 10¹⁶ | PVP | 45000 | 0.0003 | 1.62 × 10¹⁹ | KOH |
| | | | | | | | | | K2CO3 |
| | | | | | | | | | TMAH |
| Example A2 | 55 | 1.8 | 1.2 | 7.65 × 10¹⁶ | PVP | 45000 | 0.0003 | 1.62 × 10¹⁹ | KOH |
| | | | | | | | | | K2CO3 |
| | | | | | | | | | TMAH |
| Example A3 | 55 | 1.8 | 1.9 | 1.19 × 10¹⁷ | PVP | 10000 | 0.001 | 5.42 × 10¹⁹ | TMAH |
| Example A4 | 90 | 1.8 | 1.2 | 1.75 × 10¹⁶ | PVP | 45000 | 0.0003 | 1.62 × 10¹⁹ | KOH |
| | | | | | | | | | K2CO3 |
| | | | | | | | | | TMAH |
| Example A5 | 90 | 1.8 | 1.2 | 1.75 × 10¹⁶ | PVP | 45000 | 0.0003 | 1.62 × 10¹⁹ | KOH |
| | | | | | | | | | K2CO3 |
| | | | | | | | | | TMAH |
| Example A6 | 100 | 2.2 | 1.2 | 1.04 × 10¹⁶ | PVP | 45000 | 0.0003 | 1.62 × 10¹⁹ | TMAH |
| Example A7 | 50 | 2.2 | 1.2 | 8.33 × 10¹⁶ | PVCL | 90000 | 0.0003 | 1.30 × 10¹⁹ | KOH |
| | | | | | | | | | K2CO3 |
| | | | | | | | | | TMAH |
| Example A8 | 50 | 2.2 | 1.2 | 8.33 × 10¹⁶ | PVP | 9000 | 0.0003 | 1.62 × 10¹⁹ | KOH |
| | | | | | | | | | K2CO3 |
| | | | | | | | | | TMAH |
| Example A9 | 50 | 2.2 | 1.2 | 8.33 × 10¹⁶ | PVP | 450000 | 0.0003 | 1.62 × 10¹⁹ | KOH |
| | | | | | | | | | K2CO3 |
| | | | | | | | | | TMAH |
| Example A10 | 50 | 2.2 | 1.2 | 8.33 × 10¹⁶ | PVP | 1400000 | 0.0003 | 1.62 × 10¹⁹ | KOH |
| | | | | | | | | | K2CO3 |
| | | | | | | | | | TMAH |
| Example A11 | 50 | 2.2 | 1.2 | 8.33 × 10¹⁶ | PVP | 45000 | 0.001 | 5.42 × 10¹⁹ | KOH |
| | | | | | | | | | K2CO3 |
| | | | | | | | | | TMAH |
| Example A12 | 50 | 2.2 | 1.2 | 8.33 × 10¹⁶ | PVP | 45000 | 0.0003 | 1.62 × 10¹⁹ | KOH |
| Example A13 | 50 | 2.2 | 1.2 | 8.33 × 10¹⁶ | PVP | 45000 | 0.0003 | 1.62 × 10¹⁹ | TMAH |
| Comparative | 12 | 1.8 | 1.2 | 7.37 × 10¹⁸ | PVP | 45000 | 0.0003 | 1.62 × 10¹⁹ | KOH |
| Example A1 | | | | | | | | | K2CO3 |
| | | | | | | | | | TMAH |
| Comparative | 35 | 1.8 | 1.2 | 2.70 × 10¹⁷ | PVP | 45000 | 0.0003 | 1.62 × 10¹⁹ | KOH |
| Example A2 | | | | | | | | | K2CO3 |
| | | | | | | | | | TMAH |
| Comparative | 50 | 2.2 | 1.2 | 8.33 × 10¹⁶ | PVP | 45000 | 0.0003 | 1.62 × 10¹⁹ | TMAH |
| Example A3 | | | | | | | | | |
| Comparative | 50 | 2.2 | 0.2 | 1.39 × 10¹⁶ | PVP | 45000 | 0.0003 | 1.62 × 10¹⁹ | TMAH |
| Example A4 | | | | | | | | | |
| Comparative | 50 | 2.2 | 1.2 | 8.33 × 10¹⁶ | PAA | 25000 | 0.0003 | 2.51 × 10¹⁹ | KOH |
| Example A5 | | | | | | | | | K2CO3 |
| | | | | | | | | | TMAH |
| Comparative | 50 | 2.2 | 1.2 | 8.33 × 10¹⁶ | PVA | 53000 | 0.0003 | 4.10 × 10¹⁹ | KOH |
| Example A6 | | | | | | | | | K2CO3 |
| | | | | | | | | | TMAH |
| Comparative | 50 | 2.2 | 1.2 | 8.33 × 10¹⁶ | PEG | 20000 | 0.0003 | 4.10 × 10¹⁹ | KOH |
| Example A7 | | | | | | | | | K2CO3 |
| | | | | | | | | | TMAH |
| Comparative | 50 | 2.2 | 1.2 | 8.33 × 10¹⁶ | — | — | — | — | KOH |
| Example A8 | | | | | | | | | K2CO3 |
| | | | | | | | | | TMAH |
| Comparative | 50 | 2.2 | 1.2 | 8.33 × 10¹⁶ | — | — | — | — | TMAH |
| Example A9 | | | | | | | | | |

| | Basic compound | | | | | | | | |
|---|---|---|---|---|---|---|---|---|---|
| | Content | | | | | Surface | Surface | Edge | Edge |
| | [% by | | | | Polishing | roughness | roughness | shape | shape |
| | mass] | C | B/A | C/A | rate | Ra | Rt | A1 | A2 |
| Example A1 | 0.004 | 4.15 × 10²¹ | 195 | 49800 | ∘∘ | ∘∘ | ∘∘ | ∘∘ | ∘∘ |
| | 0.04 | | | | | | | | |
| | 0.03 | | | | | | | | |
| Example A2 | 0.004 | 4.15 × 10²¹ | 212 | 54300 | ∘ | ∘∘ | ∘ | ∘ | ∘ |
| | 0.04 | | | | | | | | |
| | 0.03 | | | | | | | | |
| Example A3 | 0.2 | 1.32 × 10²² | 447 | 109000 | ∘ | Δ | ∘ | Δ | — |
| Example A4 | 0.004 | 4.15 × 10²¹ | 930 | 238000 | ∘∘ | Δ | ∘ | Δ | — |
| | 0.04 | | | | | | | | |
| | 0.03 | | | | | | | | |
| Example A5 | 0.002 | 1.31 × 10²¹ | 930 | 75000 | ∘∘ | ∘ | ∘ | ∘ | — |
| | 0.01 | | | | | | | | |
| | 0.01 | | | | | | | | |
| Example A6 | 0.2 | 1.32 × 10²² | 1560 | 1270000 | ∘ | Δ | ∘∘ | Δ | — |
| Example A7 | 0.004 | 4.15 × 10²¹ | 156 | 49800 | ∘∘ | ∘∘ | ∘ | ∘ | — |
| | 0.04 | | | | | | | | |
| | 0.03 | | | | | | | | |
| Example A8 | 0.004 | 4.15 × 10²¹ | 195 | 49800 | ∘∘ | ∘∘ | ∘∘ | ∘ | — |
| | 0.04 | | | | | | | | |
| | 0.03 | | | | | | | | |
| Example A9 | 0.004 | 4.15 × 10²¹ | 195 | 49800 | ∘ | ∘∘ | ∘∘ | ∘∘ | — |
| | 0.04 | | | | | | | | |
| | 0.03 | | | | | | | | |
| Example A10 | 0.004 | 4.15 × 10²¹ | 195 | 49800 | Δ | ∘∘ | ∘∘ | ∘∘ | — |
| | 0.04 | | | | | | | | |
| | 0.03 | | | | | | | | |
| Example A11 | 0.004 | 4.15 × 10²¹ | 650 | 49800 | Δ | ∘∘ | ∘ | ∘∘ | — |
| | 0.04 | | | | | | | | |
| | 0.03 | | | | | | | | |
| Example A12 | 0.07 | 7.51 × 10²¹ | 195 | 90100 | Δ | ∘∘ | ∘∘ | ∘∘ | ∘∘ |
| Example A13 | 0.07 | 4.62 × 10²¹ | 195 | 55400 | ∘ | ∘∘ | ∘∘ | ∘ | — |
| Comparative | 0.004 | 4.15 × 10²¹ | 2 | 563 | ∘ | ∘∘ | x | ∘∘ | — |
| Example A1 | 0.04 | | | | | | | | |
| | 0.03 | | | | | | | | |
| Comparative | 0.004 | 4.15 × 10²¹ | 55 | 14000 | ∘ | ∘∘ | x | ∘∘ | — |
| Example A2 | 0.04 | | | | | | | | |
| | 0.03 | | | | | | | | |
| Comparative | 0.002 | 1.32 × 10²⁰ | 195 | 1580 | x | Δ | ∘ | ∘∘ | — |
| Example A3 | | | | | | | | | |
| Comparative | 0.4 | 2.64 × 10²² | 1170 | 1900000 | Δ | x | ∘ | x | — |
| Example A4 | | | | | | | | | |
| Comparative | 0.004 | 4.15 × 10²¹ | 301 | 49800 | ∘ | ∘∘ | Δ | x | — |
| Example A5 | 0.04 | | | | | | | | |
| | 0.03 | | | | | | | | |
| Comparative | 0.004 | 4.15 × 10²¹ | 492 | 49800 | x | ∘∘ | Δ | Δ | — |
| Example A6 | 0.04 | | | | | | | | |
| | 0.03 | | | | | | | | |
| Comparative | 0.004 | 4.15 × 10²¹ | 492 | 49800 | x | ∘∘ | Δ | Δ | — |
| Example A7 | 0.04 | | | | | | | | |
| | 0.03 | | | | | | | | |
| Comparative | 0.004 | 4.15 × 10²¹ | — | 49800 | ∘∘ | x | ∘∘ | x | x |
| Example A8 | 0.04 | | | | | | | | |
| | 0.03 | | | | | | | | |
| Comparative | 0.07 | 4.62 × 10²¹ | — | 55400 | ∘ | x | ∘∘ | x | — |
| Example A9 | | | | | | | | | |

TABLE 2
Polishing condition 1

| Polisher: | Double side polishing machine | |
|---|---|---|
| | (LPD-300: made by Fujikoshi | |
| | Machinery Corp.) | |
| Load: | 25 | kPa |
| Rotation speed of upper platen: | 20 | rpm |
| Rotation speed of lower platen: | 15 | rpm |
| Polishing pad: | MH-S15A (made by | |
| | Nitta Haas Incorporated) | |
| Feeding rate of Polishing composition: | 6 | L/min |
| Amount of polishing: | 10 | μm |
| Holding temperature of polishing | 25° | C. |
| composition: | | |

TABLE 3
Polishing condition 2

| Polisher: | Double side polishing machine | |
|---|---|---|
| | (DSM20B-5P-4D: made by | |
| | Speedfam Co., Ltd.) | |
| Load: | 15 | kPa |
| Rotation speed of upper platen: | 13 | rpm |
| Rotation speed of lower platen: | 35 | rpm |
| Rotation speed of internal gear: | 7 | rpm |
| Rotation speed of sun gear: | 25 | rpm |
| Polishing pad: | MH-S15A (made by Nitta Haas | |
| | Incorporated) | |
| Feeding rate of polishing composition: | 4.5 | L/min |
| Amount of polishing: | 15 | μm |
| Holding temperature of polishing | 20° | C. |
| composition: | | |

As shown in Table 1, in Examples A1 to A13, all of the evaluation results of the polishing rate, the surface roughness Ra, the surface roughness Rt, and the edge shape A1 were “oo”, “o”, or “Δ”, which was satisfactory. In contrast, in Comparative Examples A1 to A9, some of the evaluation results of the polishing rate, the surface roughness Ra, the surface roughness Rt, and the edge shape A1 were “x”, which was unsatisfactory. It was found from the results that setting the value of B/A and the value of C/A of a polishing composition including silicon dioxide, a nitrogen-containing water-soluble polymer, and a basic compound to a predetermined range allowed the edge shape of a polishing object to be maintained, the surface roughness or the difference in level to be easily reduced, and a high polishing rate to be easily obtained.

It was found that although the evaluation of the edge shape A2 was based on the evaluation of the edge shape of a silicon substrate by a different method from the method for the edge shape A1, the evaluation results had the similar tendency in the evaluation results of the edge shape A1.

### (B. One Side Polishing of Semiconductor Substrate)

Polishing compositions of Examples B1 to B10 and Comparative Examples B1 to P12 were prepared by mixing silicon dioxide, a nitrogen-containing water-soluble polymer compound, and a basic compound with on exchange water. The details for each of the polishing compositions are shown in Table 4. The abbreviations in Table 4 are the same in Table 1.

A silicon substrate was polished under the polishing condition 3 described in Table 5 with each of the polishing compositions. The silicon substrate used had a diameter of 300 mm, p-type conduction, a crystal orientation of <100>, and a resistivity of 0.1 Ω·cm or more and less than 100 Ω·cm.

### <Polishing Rate>

The thickness of a silicon substrate before polishing and the thickness of the silicon substrate after polishing under the polishing condition 3 were measured with Nanometro 300TT, made by Kuroda Precision Industries Ltd., and the difference in thickness before and after polishing was divided by polishing time so as to calculate the polishing rate. In the “polishing rate” column of Table 4, “oo” represents a polishing rate of 0.30 μm/min or more, “o” represents a polishing rate of 0.25 μm/min or more and less than 0.30 μm/min, “Δ” represents a polishing rate of 0.20 μm/min or more and less than 0.25 μm/min, and “x” represents a polishing rate of less than 0.20 μm/min.

### <Surface Roughness or Difference in Level>

The surface roughness Ra of a silicon substrate after polishing under the polishing condition 3 was measured with “ZYGO New View 5010”, made by Zygo Corporation. The surface roughness Ra is a parameter that indicates the average of amplitude in the height direction of a roughness curve, representing the arithmetic average of surface height of a silicon substrate within a fixed visual field. In the “surface roughness Ra” column of Table 4, “oo” represents a surface roughness Ra of less than 6.0 Å, “o” represents 6.0 Å or more and less than 7.0 Å, “Δ” represents 7.0 Å or more and less than 8.0 Å, and “x” represents 8.0 Å or more.

The surface roughness Rt of a silicon substrate after polishing under the polishing condition 3 was measured with HRP340, made by KLA-Tencor Corporation. The surface roughness Rt is a parameter that indicates the maximum sectional height of a roughness curve, representing the difference between the highest part and the lowest part of the surface height of a silicon substrate within a fixed visual field. In the “surface roughness Rt” column of Table 4, “oo” represents a surface roughness Rt of less than 300 Å, “o” represents 300 Å or more and less than 700 Å, “Δ” represents 700 Å or more and less than 1,500 Å, and “x” represents 1,500 Å or more.

### <Edge Shape B1>

The SFQR value indicating the flatness of a substrate was measured for each of the silicon substrates before polishing and the silicon substrates after polishing under the polishing condition 3, so that the edge shape of the silicon substrate after polishing was evaluated based on the difference in SFQR value before and after polishing. More specifically, 30 pieces of 25 mm square regions were arranged on each of the substrates, excluding notches on the periphery of the substrate, for measurement of the SFQR value for each of the regions with Nanometro 300TT, made by Kuroda Precision Industries Ltd., and the average of the difference in SFQR value between before and after polishing was obtained. In the “edge shape B1” column of Table 4, “oo” represents an average of less than 0.2 μm, “o” represents an average of 0.2 μm or more and less than 0.3 μm, “Δ” represents 0.3 μm and more and less than 0.4 μm, and “x” represents 0.5 μm or more.

TABLE 4

| | Silicon dioxide | | | | Water-soluble polymer | | | | |
|---|---|---|---|---|---|---|---|---|---|
| | BET | True | | | | Weight | | | Basic |
| | particle | specific | Content | | | average | Content | | com- |
| | diameter | gravity | [% by | | | molecular | [% by | | pound |
| | [nm] | [g/cm³] | mass] | A | Kind | weight | mass] | B | Kind |
| Example B1 | 50 | 2.2 | 1.2 | 8.33 × 10¹⁶ | PVP | 45000 | 0.0003 | 1.62 × 10¹⁹ | KOH |
| | | | | | | | | | K2CO3 |
| | | | | | | | | | TMAH |
| Example B2 | 55 | 1.8 | 1.2 | 7.65 × 10¹⁶ | PVP | 45000 | 0.0003 | 1.62 × 10¹⁹ | KOH |
| | | | | | | | | | K2CO3 |
| | | | | | | | | | TMAH |
| Example B3 | 90 | 1.8 | 1.2 | 1.75 × 10¹⁶ | PVP | 45000 | 0.0003 | 1.62 × 10¹⁹ | KOH |
| | | | | | | | | | K2CO3 |
| | | | | | | | | | TMAH |
| Example B4 | 50 | 2.2 | 1.2 | 8.33 × 10¹⁶ | PVCL | 90000 | 0.0003 | 1.30 × 10¹⁹ | KOH |
| | | | | | | | | | K2CO3 |
| | | | | | | | | | TMAH |
| Example B5 | 50 | 2.2 | 1.2 | 8.33 × 10¹⁶ | PVP | 9000 | 0.0003 | 1.62 × 10¹⁹ | KOH |
| | | | | | | | | | K2CO3 |
| | | | | | | | | | TMAH |
| Example B6 | 50 | 2.2 | 1.2 | 8.33 × 10¹⁶ | PVP | 450000 | 0.0003 | 1.62 × 10¹⁹ | KOH |
| | | | | | | | | | K2CO3 |
| | | | | | | | | | TMAH |
| Example B7 | 50 | 2.2 | 1.2 | 8.33 × 10¹⁶ | PVP | 1400000 | 0.0003 | 1.62 × 10¹⁹ | KOH |
| | | | | | | | | | K2CO3 |
| | | | | | | | | | TMAH |
| Example B8 | 50 | 2.2 | 1.2 | 8.33 × 10¹⁶ | PVP | 45000 | 0.001 | 5.42 × 10¹⁹ | KOH |
| | | | | | | | | | K2CO3 |
| | | | | | | | | | TMAH |
| Example B9 | 50 | 2.2 | 1.2 | 8.33 × 10¹⁶ | PVP | 45000 | 0.0003 | 1.62 × 10¹⁹ | KOH |
| Example B10 | 50 | 2.2 | 1.2 | 8.33 × 10¹⁹ | PVP | 45000 | 0.0003 | 1.62 × 10¹⁹ | TMAH |
| Comparative | 12 | 1.8 | 1.2 | 7.37 × 10¹⁸ | PVP | 45000 | 0.0003 | 1.62 × 10¹⁹ | KOH |
| Example B1 | | | | | | | | | K2CO3 |
| | | | | | | | | | TMAH |
| Comparative | 35 | 1.8 | 1.2 | 2.70 × 10¹⁷ | PVP | 45000 | 0.0003 | 1.62 × 10¹⁹ | KOH |
| Example B2 | | | | | | | | | K2CO3 |
| | | | | | | | | | TMAH |
| Comparative | 50 | 2.2 | 1.2 | 8.33 × 10¹⁶ | PVP | 45000 | 0.0003 | 1.62 × 10¹⁹ | TMAH |
| Example B3 | | | | | | | | | |
| Comparative | 50 | 2.2 | 0.2 | 1.39 × 10¹⁶ | PVP | 45000 | 0.0003 | 1.62 × 10¹⁹ | TMAH |
| Example B4 | | | | | | | | | |
| Comparative | 50 | 2.2 | 1.2 | 8.33 × 10¹⁶ | PAA | 25000 | 0.0003 | 2.51 × 10¹⁹ | KOH |
| Example B5 | | | | | | | | | K2CO3 |
| | | | | | | | | | TMAH |
| Comparative | 50 | 2.2 | 1.2 | 8.33 × 10¹⁶ | PVA | 53000 | 0.0003 | 4.10 × 10¹⁹ | KOH |
| Example B6 | | | | | | | | | K2CO3 |
| | | | | | | | | | TMAH |
| Comparative | 50 | 2.2 | 1.2 | 8.33 × 10¹⁶ | PEG | 20000 | 0.0003 | 4.10 × 10¹⁹ | KOH |
| Example B7 | | | | | | | | | K2CO3 |
| | | | | | | | | | TMAH |
| Comparative | 50 | 2.2 | 1.2 | 8.33 × 10¹⁶ | — | — | — | — | KOH |
| Example B8 | | | | | | | | | K2CO3 |
| | | | | | | | | | TMAH |
| Comparative | 50 | 2.2 | 1.2 | 8.33 × 10¹⁶ | — | — | — | — | TMAH |
| Example B9 | | | | | | | | | |
| Comparative | 55 | 1.8 | 1.9 | 1.19 × 10¹⁷ | PVP | 10000 | 0.001 | 5.42 × 10¹⁹ | TMAH |
| Example B10 | | | | | | | | | |
| Comparative | 90 | 1.8 | 1.2 | 1.75 × 10¹⁶ | PVP | 45000 | 0.0003 | 1.62 × 10¹⁹ | KOH |
| Example B11 | | | | | | | | | K2CO3 |
| | | | | | | | | | TMAH |
| Comparative | 100 | 2.2 | 1.2 | 1.04 × 10¹⁶ | PVP | 45000 | 0.0003 | 1.62 × 10¹⁹ | TMAH |
| Example B12 | | | | | | | | | |

| | Basic compound | | | | | | | |
|---|---|---|---|---|---|---|---|---|
| | Content | | | | | Surface | Surface | Edge |
| | [% by | | | | Polishing | roughness | roughness | shape |
| | mass] | C | B/A | C/A | rate | Ra | Rt | B1 |
| Example B1 | 0.004 | 4.15 × 10²¹ | 195 | 49800 | ∘∘ | ∘∘ | ∘∘ | ∘∘ |
| | 0.04 | | | | | | | |
| | 0.03 | | | | | | | |
| Example B2 | 0.004 | 4.15 × 10²¹ | 212 | 54300 | ∘ | ∘∘ | ∘ | ∘ |
| | 0.04 | | | | | | | |
| | 0.03 | | | | | | | |
| Example B3 | 0.002 | 1.31 × 10²¹ | 930 | 75000 | ∘∘ | Δ | ∘ | ∘ |
| | 0.01 | | | | | | | |
| | 0.01 | | | | | | | |
| Example B4 | 0.004 | 4.15 × 10²¹ | 156 | 49800 | ∘∘ | ∘∘ | ∘ | ∘ |
| | 0.04 | | | | | | | |
| | 0.03 | | | | | | | |
| Example B5 | 0.004 | 4.15 × 10²¹ | 195 | 49800 | ∘∘ | ∘ | ∘∘ | ∘ |
| | 0.04 | | | | | | | |
| | 0.03 | | | | | | | |
| Example B6 | 0.004 | 4.15 × 10²¹ | 195 | 49800 | ∘ | ∘∘ | ∘∘ | ∘∘ |
| | 0.04 | | | | | | | |
| | 0.03 | | | | | | | |
| Example B7 | 0.004 | 4.15 × 10²¹ | 195 | 49800 | Δ | ∘∘ | ∘∘ | ∘∘ |
| | 0.04 | | | | | | | |
| | 0.03 | | | | | | | |
| Example B8 | 0.004 | 4.15 × 10²¹ | 650 | 49800 | Δ | ∘∘ | ∘ | ∘∘ |
| | 0.04 | | | | | | | |
| | 0.03 | | | | | | | |
| Example B9 | 0.07 | 7.51 × 10²¹ | 195 | 90100 | Δ | ∘∘ | ∘∘ | ∘∘ |
| Example B10 | 0.07 | 4.62 × 10²¹ | 195 | 55400 | ∘ | ∘ | ∘∘ | ∘ |
| Comparative | 0.004 | 4.15 × 10²¹ | 2 | 563 | ∘ | ∘∘ | x | ∘∘ |
| Example B1 | 0.04 | | | | | | | |
| | 0.03 | | | | | | | |
| Comparative | 0.004 | 4.15 × 10²¹ | 55 | 14000 | ∘ | ∘∘ | x | ∘∘ |
| Example B2 | 0.04 | | | | | | | |
| | 0.03 | | | | | | | |
| Comparative | 0.002 | 1.32 × 10²⁰ | 195 | 1580 | x | x | ∘ | ∘∘ |
| Example B3 | | | | | | | | |
| Comparative | 0.4 | 2.64 × 10²² | 1170 | 1900000 | Δ | x | ∘ | x |
| Example B4 | | | | | | | | |
| Comparative | 0.004 | 4.15 × 10²¹ | 301 | 49800 | ∘ | ∘ | x | x |
| Example B5 | 0.04 | | | | | | | |
| | 0.03 | | | | | | | |
| Comparative | 0.004 | 4.15 × 10²¹ | 492 | 49800 | x | ∘ | Δ | Δ |
| Example B6 | 0.04 | | | | | | | |
| | 0.03 | | | | | | | |
| Comparative | 0.004 | 4.15 × 10²¹ | 492 | 49800 | x | ∘ | Δ | Δ |
| Example B7 | 0.04 | | | | | | | |
| | 0.03 | | | | | | | |
| Comparative | 0.004 | 4.15 × 10²¹ | — | 49800 | ∘∘ | x | ∘∘ | x |
| Example B8 | 0.04 | | | | | | | |
| | 0.03 | | | | | | | |
| Comparative | 0.07 | 4.62 × 10²¹ | — | 55400 | ∘ | x | ∘∘ | x |
| Example B9 | | | | | | | | |
| Comparative | 0.2 | 1.32 × 10²² | 447 | 109000 | ∘ | x | ∘ | Δ |
| Example B10 | | | | | | | | |
| Comparative | 0.004 | 4.15 × 10²¹ | 930 | 238000 | ∘∘ | x | ∘ | Δ |
| Example B11 | 0.04 | | | | | | | |
| | 0.03 | | | | | | | |
| Comparative | 0.2 | 1.32 × 10²² | 1560 | 1270000 | ∘ | x | ∘∘ | Δ |
| Example B12 | | | | | | | | |

TABLE 5
Polishing condition 3

| Polisher: | One side polishing machine | |
|---|---|---|
| | (PNX-332B: made by Okamoto | |
| | Machine Tool Works, Ltd.) | |
| Load: | 20 | kPa |
| Rotation speed of platen: | 30 | rpm |
| Rotation speed of polishing object: | 30 | rpm |
| Polishing pad: | MH-S15A (made by Nitta Haas | |
| | Incorporated) | |
| Feeding rate of Polishing composition: | 2 | L/min |
| Polishing time: | 5 | min/batch |
| Holding temperature of polishing | 20° | C. |
| composition: | | |

As shown in Table 4, in Examples B1 to B10, all of the evaluation results of the polishing rate, the surface roughness Ra, the surface roughness Rt, and the edge shape B1 were “oo”, “o”, or “Δ”, which was satisfactory. In contrast, in Comparative Examples B1 to B12, some of the evaluation results of the polishing rate, the surface roughness Ra, the surface roughness Rt, and the edge shape B1 were “x”, which was unsatisfactory. It was found from the results that setting the value of B/A and the value of C/A of a polishing composition including silicon dioxide, a nitrogen-containing water-soluble polymer, and a basic compound to a predetermined range allowed the edge shape of a polishing object to be maintained, the surface roughness or the difference in level to be easily reduced, and a high polishing rate to be easily obtained.

1. A polishing composition to be used for polishing both surfaces of a semiconductor substrate, comprising silicon dioxide, a nitrogen-containing water-soluble polymer, and a basic compound, wherein
the silicon dioxide has an average primary particle diameter of 40 nm or more as calculated from a specific surface area of the silicon dioxide determined by a BET method, and
B/A is 1 or more and less than 7,000 and C/A is 5,000 or more and less than 1,500,000 when in one liter of the polishing composition, A is defined as the number of silicon dioxide, B is defined as the number of monomer units of the nitrogen-containing water-soluble polymer, and C is defined as the number of molecules of the basic compound.

2. A polishing composition comprising silicon dioxide, a nitrogen-containing water-soluble polymer, and a basic compound, wherein
the silicon dioxide has an average primary particle diameter of 40 nm or more as calculated from a specific surface area of the silicon dioxide determined by a BET method, and
B/A is 1 or more and less than 7,000 and C/A is 5,000 or more and less than 100,000 when in one liter of the polishing composition, A is defined as the number of silicon dioxide, B is defined as the number of monomer units of the nitrogen-containing water-soluble polymer, and C is defined as the number of molecules of the basic compound.

3. The polishing composition according to claim 1, wherein the nitrogen-containing water-soluble polymer has a weight average molecular weight of less than 1,500,000.

4. The polishing composition according to claim 1, wherein the silicon dioxide has true specific gravity of 1.7 or more.

5. The polishing composition according to claim 1, wherein the basic compound includes a potassium compound and a quaternary ammonium compound.

6. A method for producing a semiconductor substrate, comprising polishing a semiconductor substrate with the polishing composition according to claim 1.

7. The polishing composition according to claim 2, wherein the nitrogen-containing water-soluble polymer has a weight average molecular weight of less than 1,500,000.

8. The polishing composition according to claim 2, wherein the silicon dioxide has true specific gravity of 1.7 or more.

9. The polishing composition according to claim 2, wherein the basic compound includes a potassium compound and a quaternary ammonium compound.

10. A method for producing a semiconductor substrate, comprising polishing a semiconductor substrate with the polishing composition according to claim 2.
